(19) United States
(12) Patent Application Publication
(10) Pub. No.: US 2009/0132894 A1
(43) Pub. Date: May 21, 2009

(54) Soft Output Bit Threshold Error Correction

(75) Inventors: GuoFang Catherine Xu, Longmont, CO (US); Hieu V. Nguyen, Superior, CO (US); William Michael Radich, Chaska, MN (US); Michael John Link, St. Paul, MN (US)

Correspondence Address: SEAGATE TECHNOLOGY LLC C/O WESTMAN;CHAMPLIN & KELLY, P.A., SUITE 1400, 900 SECOND AVENUE SOUTH, MINNEAPOLIS, MN, 55402, US

(73) Assignee: Seagate Technology LLC, Scotts Valley, CA (US)

(21) Appl. No.: 11/942,523

(22) Filed: Nov. 19, 2007

(51) Int. Cl. H03M 13/00

(52) U.S. Cl. 714/780

(57) ABSTRACT

A communications channel is provided that includes an encoder that receives user data and generates corresponding encoded symbols for transmission through a channel medium. A channel detector has an input coupled to receive an output signal from the channel medium and a reliability information output which produces reliability information regarding logic states of detected bits in the output signal. A binary reliability value is provide for each of the detected bits. The channel further includes a decoder having a reliability information input coupled to the reliability information output of the channel detector to generate corresponding user data words as a function of the binary reliability value.

### BACKGROUND

The present disclosure relates to data channels and more particularly those that utilize soft output viterbi algorithms (SOVA).

In communication channels, data must be transmitted through the channel reliably. Data is represented as a sequence of bits, which each bit taking a value of zero or one. In most communication channels, two major components ensure the reliability of the data: a detection channel (or detector) and an error correction code (ECC). The detector receives an analog waveform from the channel, converts the analog waveform to a digital waveform, and then converts the digital waveform into ones and zeros. The ones and zeros are grouped in contiguous subsequence of bits known as symbols. Along with the symbols, an indication of reliability, known as a soft information, can be determined by the detector for each bit in the symbol. The number of bits in a symbol is determined as a parameter of the ECC and is typically a small number, such as ten. The data symbols and soft information are transmitted to an ECC decoder, where erroneous symbols are corrected, assuming that the number of symbols that the ECC has been designed to correct has not been exceeded.

A simple ECC code is based on parity. A parity bit is added to a group of data bits, such as a data word, and has a logic state that is selected to make the total number of ones (or zeros) in the data word either even or odd. The original data word is then transmitted to the channel along with the additional parity bit as a modified data word or “ECC symbol”. The ECC symbol is received from the channel and ECC decoder checks the parity of the ECC symbol against an expected value. If the parity is correct, the ECC detection circuit assumes there are no bit errors. If the parity is incorrect, the ECC detection circuit assumes there is an error in the transmitted data.

### SUMMARY

An approach to processing data within a channel is disclosed. Logic states and reliability information for the logic states are determined from a signal. The reliability information is compared to a threshold and converted to a binary value based on the comparison. Further processing can be performed based on the binary value such as flipping logic states for retry in an error correction code environment.

A communications channel is provided that includes an encoder that receives user data and generates corresponding encoded symbols for transmission through a channel medium. A channel detector has an input coupled to receive an output signal from the channel medium and a reliability information output which produces reliability information regarding logic states of detected bits in the output signal. A binary reliability value is provide for each of the detected bits. The channel further includes a decoder having a reliability information input coupled to the reliability information output of the channel detector to generate corresponding user data words as a function of the binary reliability value.

In a further aspect, a method of decoding a signal received from a channel includes receiving the signal and determining reliability information regarding logic states of detected bits in the signal. The reliability information is compared to a threshold and converted to a binary value based on the threshold. The signals are converted to a sequence of data bits as a function of the binary value.

In yet another aspect, a communication channel includes a channel detector having an input coupled to receive an output signal from the channel medium and a reliability information output which produces reliability information regarding logic states of detected bits in the output signal. A decoder includes a soft information input coupled to the reliability information output of the channel detector to generate corresponding data symbols as a function of the reliability information. An error correction code decoder is coupled to the decoder to generate user data words based on the data symbols as a function of an error correction code. A bit flip module is further provided to flip selected bits in the data symbols based on the reliability information as a function of the error correction code.

Other features and benefits that characterize embodiments of the present invention will be apparent upon reading the following detailed description and review of the associated drawings.

### BRIEF DESCRIPTION OF THE DRAWINGS

FIG. 1A is a block diagram illustrating a communications system.

FIG. 1B is a flow diagram of a method for re-trying an ECC in the system of FIG. 1A.

FIG. 2A is a block diagram of an iterative communications system.

FIG. 2B is a flow diagram of a method for re-trying an ECC in the system of FIG. 2A.

### DETAILED DESCRIPTION

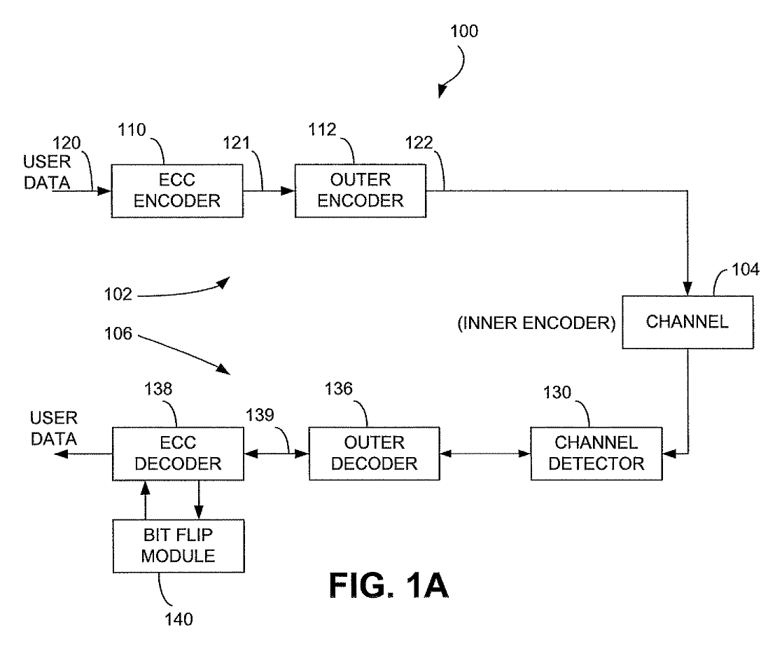

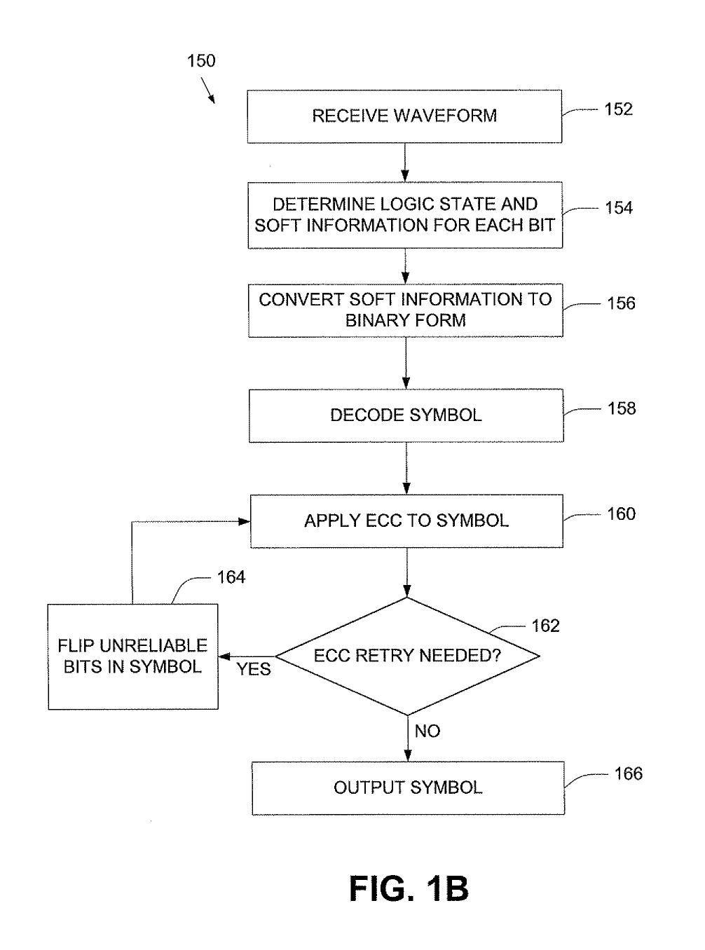

FIG. 1A is a block diagram illustrating communications system 100. System 100 can correspond to any communication channel through which data is transmitted or received, such as satellite, cellular and storage channels.

System 100 includes a transmit path 102, a channel 104 and a receive path 106. In the case of a data storage channel, transmit path 102 corresponds to a write path, receive path 106 corresponds to a read path, and channel 104 corresponds to a storage device, such as a hard disc or other memory device. Transmit path 102 includes an ECC encoder 110 and outer encoder 112. ECC encoder 110 receives a sequence of user data words 120 and produces corresponding multiple-bit ECC symbols 121. ECC encoder 110 can operate on any number of user data bits, such as individual user data words or an entire data sector. In one embodiment, ECC encoder 110 operates on a data sector.

A simple ECC code is based on parity. A parity bit is added to a group of data bits, such as a data word, and has a logic state that is selected to make the total number of ones (or zeros) in the data word either even or odd. The original data word is then passed to outer encoder 112 along with the additional parity bit as a modified data word or “ECC symbol” 121. In receive path 106, the parity of the ECC symbol can be checked against an expected value. If the parity is correct, the receive path assumes there are no bit errors. If the parity is incorrect, the receive path assumes there is an error in the transmitted data.

More complex ECC codes can also be used for enabling not only detection of additional errors but also correction of some of the detected errors. For example, a single-error correction, double-error detection (SEC-DED) Hamming code adds enough additional parity bits to enable the detection circuit to detect and correct any single-bit error in a data word and detect two-bit errors. Other types of error correction codes include convolution (tree) codes and block codes. In these types of ECC codes, one or more data words are divided into blocks of data, and each block of data is encoded into a longer block of data known as an ECC symbol, as mentioned above. With convolution codes, the encoding of one block of data depends on the state of the encoder as well as the data to be encoded. A Reed Solomon ECC codes correct symbols (groups of bits), not bits. In one embodiment, ECC encoder 110 implements a Reed Solomon Code, and each ECC symbol 121 includes one or more data bits and one or more ECC parity bits. The ECC parity bits can be concatenated to the data bits, distributed among the data bits or encoded with the data bits.

Outer encoder 112 encodes the data to encoded symbols 122 before the data is transmitted to channel 104. Outer encoder 112 can implement any suitable type of code, such as a block code, a convolution code, a Low Density Parity Check (LDPC) code, single parity check (SPC), turbo code, or a Turbo-Product Code (TPC) to add outer parity bits, for example, to the ECC symbol 121. In one embodiment, outer encoder 112 implements a TPC code, which generates a multi-dimensional array of code words using linear block codes, such as parity check codes, Hamming codes, BCH codes, etc. The simplest type of TPC code is a two-dimensional TPC single parity check (TPC/SPC) with a single parity bit per row and column. A TPC with a multiple parity check (TPC/MPC) is similar to a TPC/SPC code with the exception that there are multiple row parity bits and multiple column parity bits. The multiple parity bits provide more flexibility in code structure, code rate and code length.

In general, two-dimensional multi-parity turbo product codes are constructed from two linear binary block codes C₁ and C₂ with parameters (n₁,k₁,d₁) and (n₂,k₂ ,d₂), where (nᵢ,kᵢ,dᵢ, i=1,2, . . . ) are the code word length, user data block length and minimum distance, respectively. A two-dimensional turbo product code C=C₁×C₂ has parameters (n,k,d), where n=n₁·n₂, k=k₁·k₂, and d≧d₁d₂. Its generator matrix is the Kronecker product (also termed the direct matrix product) of the generator matrices of its component codes. For example, the Kronecker product of a 2×2 matrix A and a 3×2 matrix B is given by the following 6×4 matrix,

$$\begin{matrix}A ⊗ B = [ \begin{matrix}{a}_{11} B & {a}_{12} B \\ {a}_{21} B & {a}_{22} B\end{matrix} ] \\ = [ \begin{matrix}{a}_{11} {b}_{11} & {a}_{11} {b}_{12} & {a}_{12} {b}_{11} & {a}_{12} {b}_{12} \\ {a}_{11} {b}_{21} & {a}_{11} {b}_{22} & {a}_{12} {b}_{21} & {a}_{12} {b}_{22} \\ {a}_{11} {b}_{31} & {a}_{11} {b}_{32} & {a}_{12} {b}_{31} & {a}_{12} {b}_{32} \\ {a}_{21} {b}_{11} & {a}_{12} {b}_{12} & {a}_{22} {b}_{11} & {a}_{22} {b}_{12} \\ {a}_{21} {b}_{21} & {a}_{21} {b}_{22} & {a}_{22} {b}_{21} & {a}_{221} {b}_{22} \\ {a}_{21} {b}_{31} & {a}_{21} {b}_{32} & {a}_{22} {b}_{31} & {a}_{22} {b}_{32}\end{matrix} ]\end{matrix}$$

In the case of TPC/SPC, each row and each column satisfies a single-parity check, and the minimum distance for an m-dimensional TPC/SPC is 2 m. For applications in data storage systems, two-dimensional TPC/SPC and TPC/MPC codes are preferred for the sake of higher rates. Further, both row and column codes of a TPC code should be chosen the same to save hardware cost in a real implementation.

The input end of channel 104 can include elements such as a precoder, a modulator, etc. The output end of channel 104 can include elements such as a preamplifier, a timing circuit, an equalizer and others. In the case of a magnetic recording channel, the read/write process and equalization act as an inner encoder. However, channel 104 can include any other media, such as a twisted pair, optical fiber, satellite, cellular or any other wired or wireless digital or analog communication system.

Receiver path 106 includes a channel detector 130, an outer decoder 136, an ECC decoder 138 and a bit flip module 140. At the input side of channel detector 130, the analog waveform received from channel 104 is equalized and sampled to form a digital waveform. Channel detector 130 and outer decoder 136 then convert the digital waveform into ones and zeros. The ones and zeros are grouped into contiguous subsequences of bits known as symbols. The number of bits in a symbol is determined as a parameter of the ECC encoder 110 used in transmit path 102. The number of bits in a symbol is typically a small number such as ten. The ECC symbols are then transmitted to the ECC decoder 138, which detects and/or corrects any erroneous symbol that has not been corrected by channel detector 130 and outer decoder 136, assuming that the number of erroneous symbols does not exceed the number of symbols that the ECC code has been designed to correct.

Channel detector 130 can include any type of “soft decoder”, which produces quality “soft”(or reliability) information about each bit decision it makes. For example, channel detector 130 can include a Soft-Output Viterbi Algorithm (SOVA) detector or a Bahl, Cocke, Jelinek and Ravive (BCJR) algorithm detector. In this embodiment, channel detector 130 is described as being a SOVA detector with an outer decoder 136. However, it is to be understood that these are implemented-specific and can be replaced by other blocks that accomplish the same goals of detecting the data and producing soft (reliability) information and of processing of the data to resolve the parity of the outer code.

For each bit position “u” in the received digital waveform, channel detector 130 makes a soft decision, which can be expressed in terms of a log-likelihood ratio (LLR), for example, which can be defined based on the probability ratio λ=Pr{u=1}/Pr{u=0} as LLR(u)=log λ. The LLR represents the probability or confidence that the bit position is either a logic one or a zero. In some applications, it is more convenient to use log λ as a soft decision. The LLR ratio for each bit position can be expressed in terms of a signed number. For example, the signed numbers can range from +10 to −10. The sign of the number represents the likely state of the bit, with a “+” representing a logic one and a “−” representing a logic zero. The magnitude of the number represents the degree of confidence channel detector 130 has in the particular state. For example, a +1 can indicate that the bit might be a logic 1, but it's not sure. A +5 can indicate that the bit is probably a logic one and a +10 can represent that the bit is almost certainly logic one. Whereas, a −4 may reflect that the bit is probably a logic zero.

To reduce complexity of system 100, the LLR is converted to a binary value, for example “zero” or “one ”. To convert the LLR to a binary value, the LLR can be compared to a threshold to determine if the associated bit is reliable. If the LLR is above the threshold, the associated bit is determined to be reliable. Otherwise, the associated bit is determined to be unreliable. The binary reliability information is passed from channel detector 130 to outer decoder 136. This information is accompanied by hard decisions from channel detector 130 as to the logic status for each bit position.

Outer decoder 136 decodes the outer code implemented by outer encoder 112 and provides corresponding decoded symbols 139. ECC encoder 138 receives the symbols generated by outer decoder 136 and decodes the symbols into corresponding user data words. The ECC code implemented by ECC encoder 110 allows ECC decoder 138 to detect and/or correct erroneous symbols, assuming the number of symbols that the ECC has been designed to correct has not been exceeded. If the number of symbols that the ECC has been designed to correct has been exceeded, the symbols 139 generated by outer encoder 136 can be sent to bit flip module 140 along with the respective binary reliability information.

Bit flip module 140 can flip (i.e. change a logical one to a logical zero and vice versa) the bits in symbols 139 based on reliability information for the bits and an encoding method utilized by system 100. For example, if the encoding method does not utilize parity, each of the bits having reliability information below the threshold (for example determined by the binary valve for the reliability information) can be flipped. If the symbols include the bits “0 1 0 0 0 1 1 1 0 1”, wherein the underlined bits have an LLR below the threshold, the underlined bits are filpped, resulting in the bits “0 1 1 0 0 0 1 1 0 1”. The flipped symbols can be sent back to ECC decoder 138. ECC decoder 138 can then detect and/or correct erroneous symbols by performing an ECC retry routine.

If parity is employed in system 100, symbols 139 that have not been corrected by ECC decoder 138 can have bits flipped to meet a corresponding parity equation. For example, using the same symbols “0 1 0 0 0 1 1 1 0 1” and parity is even (meaning the number of ones in the symbols is even), only one of the unreliable (underlined) bits is flipped. For instance, the unreliable “0” could be flipped to provide the symbols “0 1 1 0 0 1 1 1 0 1” and these symbols can be sent by it flip module 140 to ECC decoder 138 to correct erroneous symbols therein.

FIG. 1B is a flow diagram of a method 150 performed by system 100, Method 150 begins at step 152, wherein a waveform indicative of a symbol is received by channel detector 130. A logic state determination (i.e. hard decision) as well as soft information (i.e. reliability information) determination is made for each bit at step 154. The soft information is converted to a binary form by comparing the soft information to a threshold at step 156. Thus, instead of comprising multiple bits, the reliability information is converted to a single binary value. This conversion can reduce the complexity of system 100 and thus save time and calculation costs throughout system 100. At step 158, the symbol is decoded by outer decoder 136.

ECC is applied to the symbol at step 160. The ECC will detect and/or correct errors in the symbol. If the number of errors the ECC has been designed to correct has been exceeded, an ECC re-try is needed to attempt to correct the symbol. A determination is made at step 162 as to whether an ECC re-try is needed. If re-try is needed, unreliable bits in the symbol, as determined by the binary soft information determined in step 156, are flipped at step 164 depending on the parity of system 100. For example, if no parity is used in system 100, all unreliable bits are flipped. If parity is used utilized in system 100, all the unreliable bits are flipped in order to meet a parity equation for system 100. The flipped hard decision is passed to the error correction code system and an ECC re-try is performed at step 160. The flipping of bits and ECC re-try can improve the performance of system 100. If, during ECC application, the symbol is without errors or the errors can be corrected, the symbol is output at step 166.

In addition to system 100, binary reliability information can be used in a system that uses an iterative decoding method. The method is called “iterative”(or “turbo”) decoding, because the data is processed multiple times in the detector. In an iterative decoder, special coding (parity and interleaving are two of several options) is introduced before the data is transmitted to the channel. When the data is received from the channel, the data runs through a “soft decoder”, which produces quality “soft” information about each bit decision it makes. The soft decisions are transferred to a block that resolves the parity based on the hard and soft information. This step is often implemented with a technique called “message passing.” Once the message passing is complete, both the soft and hard information have been altered and hopefully improved. This updated information is passed back to the soft decoder where the signal is detected again. Finally, the hard and soft detector output is sent back to the parity resolver, where the hard and soft information is once again improved. This iteration process may continue any number of times. Practically, the number of iterations is limited by the time that system has to deliver the data to the user. The result is an increased confidence or reliability of the detected data.

In a communication channel having an iterative-type of decoding system, two domains exist: a code or parity domain, in which error correction codes (ECC) are added to the user data bits, and a channel or detector domain in which the bits of the user data words and the ECC codes are interleaved (re-ordered) with one another.

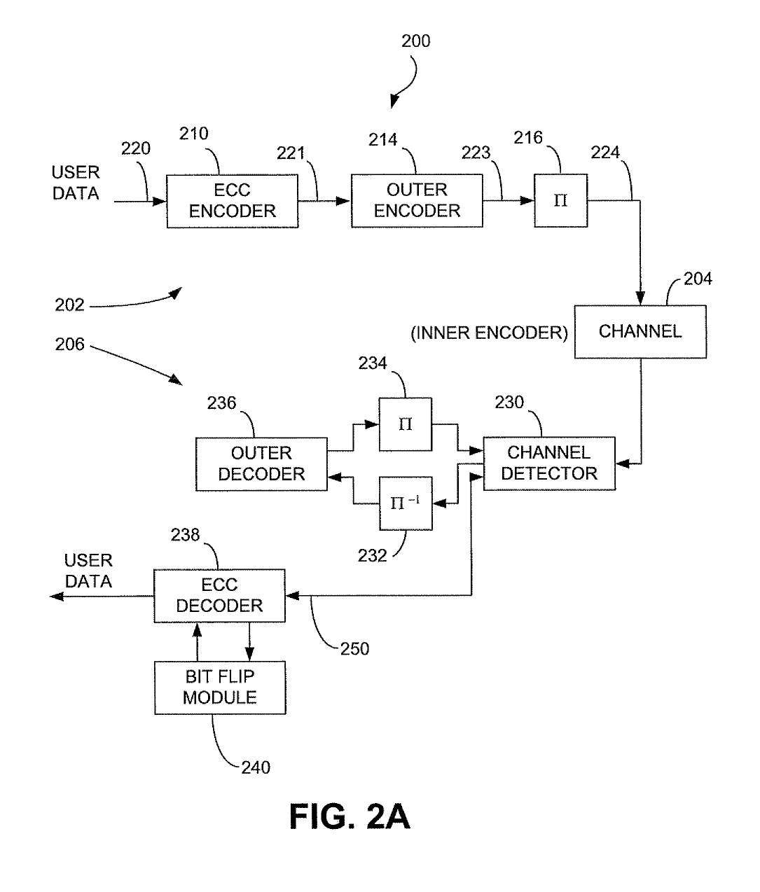

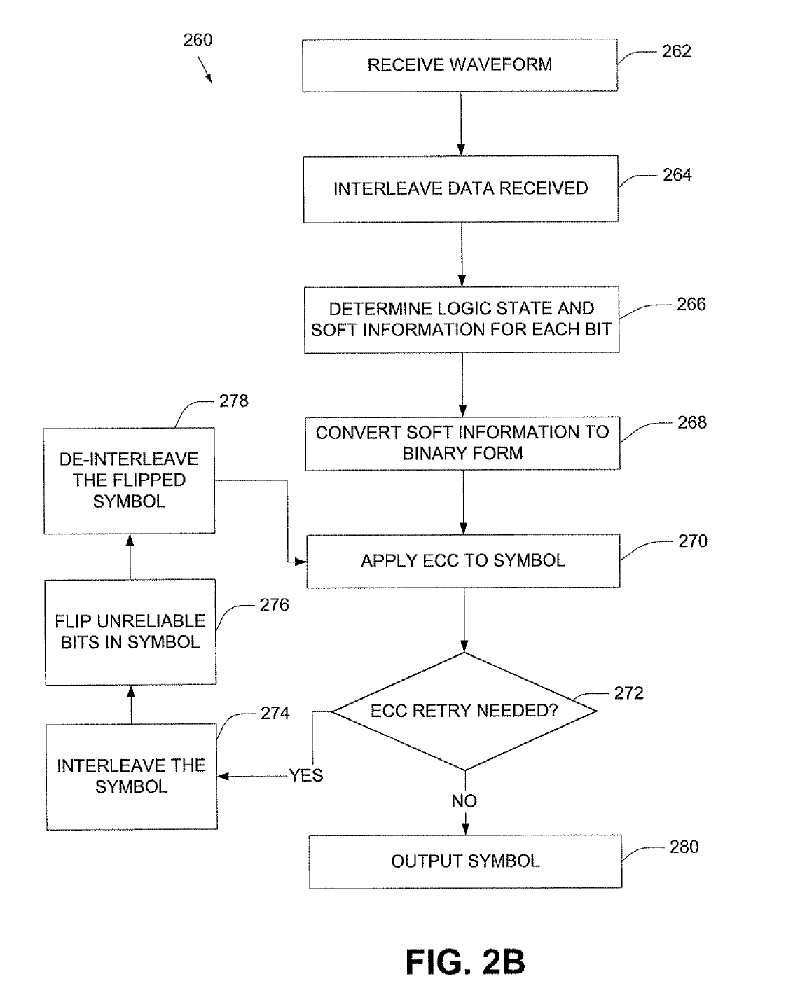

FIG. 2A is a block diagram illustrating an iterative encoding/decoding system 200. System 200 can correspond to any communication channel through which data is transmitted or received, such as satellite, cellular and storage channels.

System 200 includes a transmit path 202, a channel 204 and a receive path 206. In the case of a data storage channel, transmit path 202 corresponds to a write path, receive path 206 corresponds to a read path, and channel 204 corresponds to a storage device, such as a hard disc or other memory device. Transmit path 202 includes an ECC encoder 210, outer encoder 214 and interleaver 216. ECC encoder 210 receives a sequence of user data words 220 and produces corresponding multiple-bit ECC symbols 221. ECC encoder 210 can operate similar to ECC encoder 110 in FIG. 1.

ECC encoder generates ECC symbols 221 and transmits the symbols to outer encoder 214 as discussed above with respect to ECC encoder 110. Outer encoder further produces code words 223 as discussed above with respect to outer encoder 112. The code words 223 produced by outer encoder 214 are passed through interleaver 216, which shuffles the bits in code words 223 in a pseudo-random fashion to produce interleaved code words 224 for transmission through channel 204.

The input end of channel 204 can include elements such as a precoder, a modulator, etc. The output end of channel 204 can include elements such as a preamplifier, a timing circuit, an equalizer and others. In the case of a magnetic recording channel, the read/write process and equalization act as an inner encoder. However, channel 204 can include any other media, such as a twisted pair, optical fiber, satellite, cellular or any other wired or wireless digital or analog communication system.

Receiver path 206 includes a channel detector 230, a de-interleaver 232, an interleaver 234, an outer decoder 236, an ECC decoder 238 and a bit flip module 240. At the input side of channel detector 230, the analog waveform received from channel 204 is equalized and sampled to form a digital waveform. Channel detector 230 and outer decoder 236 then convert the digital waveform into ones and zeros. The ones and zeros are grouped into contiguous subsequences of bits known as symbols. The number of bits in a symbol is determined as a parameter of the ECC encoder 210 used in transmit path 202. The number of bits in a symbol is typically a small number such as ten. The ECC symbols are then transmitted to the ECC decoder 238, which detects and/or corrects any erroneous symbol that has not been corrected by channel detector 230 and outer decoder 236, assuming that the number of erroneous symbols does not exceed the number of symbols that the ECC code has been designed to correct.

As discussed above with respect to channel detector 130, channel detector 230 can include any type of “soft decoder”, which produces quality “soft” information about each bit decision it makes. For example, channel detector 230 can include a Soft-Output Viterbi Algorithm (SOVA) detector or a Bahl, Cocke, Jelinek and Ravive (BCJR) algorithm detector. In this embodiment, channel detector 230 is described as being a SOVA detector with an outer decoder 236. However, it is to be understood that these are implemented-specific and can be replaced by other blocks that accomplish the same goals of detecting the data and producing soft (reliability) information and of processing of the data to resolve the parity of the outer code.

For each bit position “u” in the received digital waveform, channel detector 230 makes a soft decision, which can be expressed in terms of a log-likelihood ratio (LLR), for example, which can be defined based on the probability ratio λ=Pr{u=1}/Pr{u=0} as LLR(u)=log λ. The LLR represents the probability or confidence that the bit position is either a logic one or a zero. In some applications, it is more convenient to use log λ as a soft decision. The LLR ratio for each bit position can be expressed in terms of a signed number. For example, the signed numbers can range from +10 to −10. The sign of the number represents the likely state of the bit, with a “+” representing a logic one and a “−” representing a logic zero. The magnitude of the number represents the degree of confidence channel detector 230 has in the particular state. For example, a +1 can indicate that the bit might be a logic 1, but it's not sure. A +5 can indicate that the bit is probably a logic one and a +10 can represent that the bit is almost certainly logic one. Whereas, a −4 may reflect that the bit is probably a logic zero.

As in system 100, the LLR can be converted to binary value by comparing the LLR to a threshold. If the LLR is above the threshold, the associated bit is reliable. Otherwise, the bit is unreliable.

The bit positions in the sequence at the output of channel detector 230 are in the order that the bit positions were transmitted through channel 204. De-interleaver 232 re-arranges the bit positions to place the bits (soft information) in the order in which they were originally encoded by outer encoder 214. Based on the soft information provided by channel detector 230, outer decoder 236 resolves the corresponding outer parity bits for each code word or set of code words. Outer decoder 236 decodes the outer code implemented by outer encoder 214 and, based on the results of the parity checks generates altered (hopefully improved) soft information as to the confidence or reliability of each bit decision. The soft decisions produced by outer decoder 236 are generated with a technique called “message passing.” For example, outer decoder 236 can upgrade or degrade the soft information depending on whether the outer parity bits match or do not match the corresponding data in the code word. The soft information can be degraded by altering the binary reliability information value from reliable to unreliable. The soft information can be upgraded by altering the binary reliability information from unreliable to reliable.

Once the message passing algorithm is complete, the updated soft information is passed back to channel detector 230 through interleaver 234. Interleaver 234 reorders the soft information back into the bit order of the channel domain. Channel detector 230 uses the updated soft information provided by outer decoder 236 as extrinsic information and again detects the signal received from channel 204 to produce further updated soft bit decisions. These soft bit decisions are again passed to outer decoder 236 through de-interleaver 232. This iteration process may continue any number of times. When the iteration process is complete, channel detector 230 makes hard decisions as to the logic states of each bit position based on the binary reliability information and provides symbols 250 to ECC decoder 238.

ECC decoder 238 receives the hard decisions 250 generated by channel detector 230 and decodes the hard decisions into corresponding user data words. The ECC code implemented by ECC encoder 210 allows ECC decoder 238 to detect and/or correct erroneous symbols, assuming the number of symbols that the ECC has been designed to correct has not been exceeded.

If the number of symbols that the ECC has been designed to correct has been exceeded, the symbols 250 generated by channel detector 230 can be sent to bit flip module 240 along with the respective binary reliability information. Bit module 240 can flip the bits in symbols 250 based on the reliability information for the bits and an encoding method utilized by system 200. For example, symbols 250 can be sent through interleaver 234 or be interleaved within bit flip module 240. The intervleaved bits that have unreliable bits are then flipped. The flipping can also be performed in order to meet a parity equation for system 200. The flipped bits can then be de-interleaved using de-interleaver 232 or a de-interleaver provided in bit flip module 240. The flipped de-interleved symbols can then be presented to ECC decoder 238.

FIG. 2B is a flow diagram of a method 260 performed in system 200. At step 262, a waveform indicative of a symbol that includes a plurality of bits is received by detector 230. The data received is interleaved at step 264, as discussed above with regard to channel detector 230, de-interleaver 232, interleaver 234 and outer decoder 236. After interleaving, a logic state (i.e., hard decision) and soft information (i.e., reliability information) for each bit is determined at step 266. At step 268, the soft information is converted to a binary format based on a comparison with a threshold. For example, if the reliability information value is above a particular threshold, the binary form of the soft information will be ‘1,’ denoting that the value is reliable. Otherwise, the binary value will be ‘0.’

ECC is then applied to the hard decision at step 270. After application of ECC, a determination of whether an ECC re-try is needed is made at step 272. If ECC re-try is needed, method 260 proceeds to step 274. At step 274, the hard decision is interleaved. At step 276, the unreliable bits from the interleaved hard decision are flipped in order to meet a parity equation for system 200. The flipped symbol is de-interleaved at step 278 and then sent for ECC re-try at step 270. If desired, the entire event can be flipped if any of the bits were flipped in step 276. If it is determined that ECC re-try is not needed at step 272, and thus there are no errors or the errors were corrected by the ECC, the symbol is output at step 280.

It is to be understood that even though numerous characteristics and advantages of various embodiments of the invention have been set forth in the foregoing description, together with details of the structure and function of various embodiments of the invention, this disclosure is illustrative only, and changes may be made in detail, especially in matters of structure and arrangement of parts within the principles of the present invention to the full extent indicated by the broad general meaning of the terms in which the appended claims are expressed. For example, the particular elements may vary depending on the particular application for the encoding/decoding system while maintaining substantially the same functionality without departing from the scope and spirit of the present invention. In addition, although the embodiment described herein is directed to a SOVA detector, it will be appreciated by those skilled in the art that the teachings of the present invention can be applied to other “soft” output detectors without departing from the scope and spirit of the present invention. Also, the terms “de-interleaver” and “interleaver” as used in the specification and claims are interchangeable.

What is claimed is:

1. A communications channel, comprising:
a channel detector adapted to receive a signal from a channel medium, determine logic states and reliability information regarding logic states of detected bits in the signal and convert the reliability information to a binary reliability value based on a comparison to a threshold for each of the detected bits; and
a decoder coupled to the channel detector to generate corresponding user data words as a function of the binary reliability value.

2. The communications channel of claim 1 and further comprising an encoder, which receives user data and generates the signal for transmission through the channel medium, wherein the encoder comprises an error correction code, which appends at least one ECC parity bit to each dataword in the user data to form each ECC symbol and wherein the decoder generates user data words as a function of the error correction code.

3. The communications channel of claim 2 and further comprising:
an interleaver coupled to the encoder and adapted to reorder bits of user data according to a pseudo-random algorithm; and
a de-interleaver coupled to the channel detector and adapted to reorder detected bits therefrom according to the pseudo-random algorithm.

4. The communications channel of claim 1 and further comprising:
a bit flip module coupled to the decoder and adapted to flip logic states of selected detected bits as a function of each binary reliability value for the detected bits.

5. The communications channel of claim 4 wherein the selected detected bits are flipped as a function of an error correction code.

6. The communications channel of claim 4 and further comprising an Error Correction Code (ECC) decoder adapted to detect errors in the logic states.

7. The communications channel of claim 6 wherein if a number of errors in the logic states of the signal exceeds a threshold, then the bit flip module flips unreliable logic states in the signal and the ECC decoder detects errors in the logic states of the signal after the unreliable logic states have been flipped.

8. A method of decoding a signal received from a channel, the method comprising:
receiving the signal;
determining reliability information regarding logic states of detected bits in the signal;
comparing the reliability information to a threshold;
converting the reliability information to a binary value based on the threshold; and
converting the signal to a sequence of user data bits as a function of the binary value.

9. The method of claim 8 wherein the step of convening the signal to the sequence is further performed as a function of an error correction code.

10. The method of claim 9 and further comprising:
determining if an error correction code re-try is needed;
flipping detected bits having unreliable logic states if error correction code re-try is needed; and
performing error correction code re-try using the flipped logic states.

11. The method of claim 8 and further comprising:
flipping logic states of selected bits in the detected bits as a function of the binary value.

12. The method of claim 11 wherein flipping is further performed as a function of an error correction code.

13. The method of claim 8 and further comprising:
reordering detected bits in the signal as a function of a pseudo-random algorithm.

14. A communications channel for transmitting signals through a channel medium, comprising:
a channel detector having an input coupled to receive an output signal from the channel medium and a reliability information output which produces reliability information regarding logic states of detected bits in the output signal;
a decoder having a reliability information input coupled to the reliability information output of the channel detector to generate corresponding data symbols as a function of the reliability information;
an error correction code decoder coupled to the decoder to generate user data words based on the data symbols as a function of an error correction code; and
a bit flip module coupled to the error correction code decoder and adapted to flip selected bits in the data symbols based on the reliability information as a function of the error correction code and transmit the data symbols with flipped bits to the error correction code decoder.

15. The communications channel of claim 14 wherein the channel detector is adapted to compare the reliability information to a threshold and convert the reliability information to a binary value based on the threshold.

16. The communications channel of claim 14 and further comprising:
an interleaver coupled to the decoder and adapted to reorder bits according to a pseudo random sequence and provide the reordered bits to the channel detector; and
a de-interleaver coupled to the channel detector and adapted to reorder bits according to the pseudo random sequence and pseudo reordered bits to the decoder.

17. The communications channel of claim 14 wherein the error correction code is based on parity.

18. The communications channel of claim 16 wherein the error correction code decoder detects errors in the data symbols to determine if an error correction code re-try is needed and, if so, sends the data symbols to the interleaver to reorder the bits in the data symbols and wherein the bit flip module flips the interleaved data symbols as a function of the reliability information for each data symbol.

19. The communications channel of claim 14 wherein the error correction code decoder applies the error correction code to the data symbols after the selected bits have been flipped.

20. The communications channel of claim 14 and further comprising an encoder that receives user data and transmits the data to the channel medium.
